(19) United States
(12) Patent Application Publication
(10) Pub. No.: US 2012/0286118 A1
(43) Pub. Date: Nov. 15, 2012

(54) HANDS-FREE SYSTEMS FOR ATTACHING A PERSONAL ELECTRONIC DEVICE AND METHODS FOR USING THE SAME

(76) Inventor: David Richards, Orem, UT (US)

(21) Appl. No.: 13/421,840

(22) Filed: Mar. 15, 2012

Related U.S. Application Data
(60) Provisional application No. 61/453,050, filed on Mar. 15, 2011.

(51) Int. Cl. H05K 7/00

(52) U.S. Cl. 248/299.1; 248/309.1

(57) ABSTRACT

The present invention relates to a hands-free system for attaching and securing a handheld device to a desired object. In particular, the present invention relates to a system having an attachment means whereby a personal electronic device is attached to an object. Additionally, a hands-free system is disclosed including a swivel whereby an orientation of the personal electronic device may be set and retained relative to an object attached thereto. The invention further includes systems and methods for attaching a personal electronic device to a steering wheel of a car.

### RELATED APPLICATIONS

This claims priority to U.S. Provisional Patent Application Ser. No. 61/453,050, filed Mar. 15, 2011, which is expressly incorporated herein by reference in its entirety.

### BACKGROUND OF THE INVENTION

1. Field of the Invention

The present invention relates generally to hands-free systems and methods for attaching a personal electronic device to a desired object. In particular, at least some embodiments of the present invention relate to a system of interchangeable coupling components that permit a personal electronic device to be attached to a variety of different surfaces and objects in a hands-free manner.

2. Background and Related Art

In recent years, handheld devices have become common place and well integrated into every aspect of life. In particular, features such as GPS navigation, multimedia, web browsing, electronic mail and telecommunications have become increasingly accessible and mobile. Users of handheld devices greatly benefit from the many useful programs and software applications that increase efficiency in many aspects of life. For example, handheld programs exist for real time analysis of traffic, weather, and road hazards. Use of these programs during a commute is greatly desirable, and commonly practiced by drivers. Unfortunately, a driver's inattention to the road while focusing on a handheld device often leads to dangerous driving, speeding, accidents and fatalities. As a result, many cities and states have passed legislation requiring hands-free operation of handheld devices while driving a vehicle.

One of the major drawbacks associated with hands-free operation is the inability to adequately position and view the handheld device while driving. For example, when making turns or sudden stops the unsecured handheld device will commonly slide around the interior of the car and become hidden or damaged. While there are hands-free systems currently available for securing handheld devices in a car, these systems are generally designed to accommodate a single style or model of handheld device, thereby requiring multiple hands-free systems for use with multiple types of handheld devices. Additionally, currently available hands-free car systems are not cross-compatible for retaining a handheld device for applications outside of a car.

Thus, while various systems and devices currently exist for positioning and retaining a handheld device, substantial challenges still exist. Accordingly, it would be an improvement in the art to augment or even replace current hands-free systems or techniques with other systems and/or techniques.

### SUMMARY OF THE INVENTION

The present invention relates generally to hands-free systems and methods for attaching a personal electronic device to a desired object. In particular, at least some embodiments of the present invention relate to a system of interchangeable coupling components that permit a personal electronic device to be attached to a variety of different surfaces and objects in a hands-free manner.

In some aspects of the present invention, a hands-free system is provided having an attachment means for coupling a personal electronic device to an object. The attachment means generally includes a first attachment means coupled to a base component, and a second attachment means coupled to an object. The base component is generally configured to receive, house, mount or otherwise attach to the personal electronic device. The first attachment means and the second attachment means are configured to compatibly and directly couple thereby indirectly coupling the personal electronic device to the object.

In some aspects of the present invention, a swivel component is provided to enable the personal electronic device to rotate relative to a position of the object. The swivel component is generally interposed between the first attachment means and the base component. In some embodiments a swivel component is interposed between the second attachment means and the object. Further, in some aspects of the current invention a plurality of swivel components are used in combination with a first and second attachment means.

Embodiments of the present invention may further include a clip to enable attachment of the base component to an object. The clip generally includes a spring clip and a base. In some embodiments, the base of the clip is directly coupled to the second attachment means. In other embodiments, the base of the clip is rotatably coupled to the second attachment means.

Further, in some embodiments a hands-free system in accordance with the present invention is used to attach a personal electronic device to a steering wheel of a vehicle. As such, a user may view a map, directions, or conduct a phone conversation while maintaining contact with the steering wheel of the vehicle.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE DRAWINGS

In order that the manner in which the above recited and other features and advantages of the present invention are obtained, a more particular description of the invention will be rendered by reference to specific embodiments thereof, which are illustrated in the appended drawings. Understanding that the drawings depict only typical embodiments of the present invention and are not, therefore, to be considered as limiting the scope of the invention, the present invention will be described and explained with additional specificity and detail through the use of the accompanying drawings in which:

FIG. 1 is a perspective view of a hands-free system combined with a personal electronic device in accordance with a representative embodiment of the present invention;

FIG. 2 is an exploded view of a hands-free system and personal electronic device in accordance with a representative embodiment of the present invention;

FIG. 3 is an exploded view of a hands-free system and personal electronic device including a swivel component in accordance with a representative embodiment of the present invention;

FIG. 4A is perspective view of a hands-free system in combination with a swivel clip in accordance with a representative embodiment of the present invention;

FIG. 4B is an exploded view of the swivel clip shown in FIG. 4A;

FIG. 5 is an exploded perspective view of a hands-free system and clip in accordance with a representative embodiment of the present invention;

FIG. 6A is a front view of a hands-free system coupled to a steering wheel in accordance with a representative embodiment of the present invention;

FIG. 6B is an exploded cross-section view of a hands-free system and steering wheel in accordance with a representative embodiment of the present invention;

FIG. 7A-7N are perspective views of a two-piece, hands-free system in accordance with a representative embodiment of the present invention;

FIG. 7O is a perspective view of a two-piece, hands-free system having a spacer insert in accordance with a representative embodiment of the present invention;

FIG. 8 is a perspective view of a combination attachment means and flashlight in accordance with a representative embodiment of the present invention;

FIGS. 9A-9C are perspective views of a hands-free system and retention strap attachment means in accordance with a representative embodiment of the present invention;

FIG. 10A is a perspective view of a retention strap attachment means coupled to a bicycle in accordance with a representative embodiment of the present invention;

FIG. 10B is a perspective view of a hand-free system attached to a bicycle via a retention strap attachment means in accordance with a representative embodiment of the present invention;

FIG. 10C is a perspective view of a hands-free system attached to a steering wheel via a retention strap attachment means in accordance with a representative embodiment of the present invention;

FIGS. 11A-11B are perspective views of a hand-free system having an integrated electrical connector in accordance with a representative embodiment of the present invention.

FIG. 12A is a perspective view of a lanyard attachment means in accordance with a representative embodiment of the present invention;

FIG. 12B is a perspective view of a hands-free system attached to a lanyard attachment means in accordance with a representative embodiment of the present invention;

FIG. 12C is a perspective view of a lanyard attachment means coupled to a golf bag in accordance with a representative embodiment of the present invention;

FIG. 12D is a perspective view of a hands-free system attached to a golf bag via a lanyard attachment means in accordance with a representative embodiment of the present invention; and

FIG. 12E is a perspective view of a hands-free system attached to a golf bag via a retractable lanyard and a lanyard attachment means in accordance with a representative embodiment of the present invention.

### DETAILED DESCRIPTION OF THE INVENTION

The present invention relates generally to hands-free systems and methods for attaching a personal electronic device to a desired object. In particular, at least some embodiments of the present invention relate to a system of interchangeable coupling components that permit a personal electronic device to be attached to a variety of different surfaces and objects in a hands-free manner.

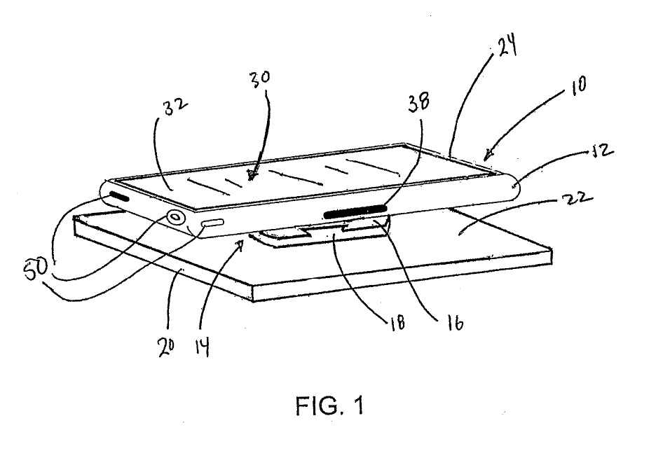

Referring to FIG. 1, a hands-free system 10 is shown as attached to a surface 22 of an object 20. A hands-free system 10 in accordance with the present invention is generally provided to attach a personal electronic device 30 to a desired object 20. A personal electronic device 30 in accordance with the present invention may comprise any mobile electronic device, including but not limited to a cellphone device, a handheld device, an iPod® device, an iPhone® device, a computer, a personal digital assistant, a smartphone, a portable media player, a handheld game console, a personal navigation device, a digital compass, a calculator, an e-book reader, a pager, a digital video camera, and a digital still camera. The hands-free system 10 generally provides means whereby a position of the personal electronic device 30 is maintained relative to an object 20, without the aid of a user's hands.

An object 20 in accordance with the present invention may include any article, device, surface, material, component, product, or a combination thereof to which a user may desire to attach a personal electronic device 20. Non-limiting examples of an object 20 include a person, a table, a dashboard, an interior surface of an automobile, a backpack, an article of clothing, a wall, an appliance, a steering wheel, a bicycle, handlebars, a chair, a headrest, a bed, an armband, a wristband, a desk, a window, and a windshield. One of skill in the art will appreciate that the specific means by which various components of the present invention are attached to personal electronic devices 20 and objects 20 will vary dependent upon the specific properties of the object 20. As such, the foregoing examples are non-limiting but rather enable one of skill in the art to understand a general application of the various embodiments of the present invention.

In some embodiments, the hands-free system 10 comprises a plurality of components configured to attach a personal electronic device 30 to a desired object 20. For example, in some embodiments a hands-free system 10 includes a base component 12. The base component 12 is configured to compatibly receive and/or support a personal electronic device 30. In some embodiments, the base component 12 comprises a case or cover into which the personal electronic device 30 is inserted. In other embodiments, the base component 12 comprises a clip (not shown) having a surface for engaging and retaining an outer surface of the electronic device 30. Further, in some embodiments the base component 12 comprises a plate (not shown) having a surface for forming an interface with a portion of the electronic device 30. An interface between the electronic device 30 and the base component 12 may include a temporary or permanent adhesive whereby the base component 12 and the personal electronic device 30 are securely coupled to one another. In other embodiments, the base component 12 further includes a locking mechanism 38 configured to securely retain the electronic device 30 within a portion of the base component 12.

The base component 12 may further include features designed to accommodate use of the personal electronic device 30 while combined with the base component 12. For example, in some embodiments the base component 12 includes a plurality of holes 50 through which various buttons, dials, switches, and connector sockets of the electronic device 30 are accessed. In other embodiments, the base component 12 comprises a flexible or semi-flexible polymer material that protects the outer surface of the electronic device 30. In other embodiments, the base component 12 comprises an opening 24 through which a display screen 32 of the electronic device 30 is viewed and/or accessed. In some embodiments the base component 12 further comprises a water-proof or water-resistant enclosure so as to prevent exposure of the electronic device 30 to moisture. Further, in some embodiments the base component 12 comprises a water-proof enclosure that is generally buoyant so as to prevent the electronic device 30 from being submersed in water.

The base component 12 is indirectly coupled to an object 20 via an attachment means 14. The attachment means 14 generally comprises a first attachment means 16 directly coupled to a portion of the base component 12, and a second attachment means 18 directly coupled to a surface 22 of an object 20. The first and second attachment means 16 and 18 may be coupled to their respective surfaces by any permanent or temporary method of attachment as known in the art. For example, in some embodiments the attachment means 16 and 18 are attached to their respective surfaces by a known attachment method including, but not limited to use of an adhesive, cement, a hook and loop system, a mechanical fastener, welding, and plastic joining techniques. In other embodiments, the personal electronic device 30 and/or the object 20 is designed and manufactured to include a first attachment means 16 and/or second attachment means 18 in accordance with the present invention.

The first and second attachment means 16 and 18 are generally configured to compatibly engage one another such that the base component 12 and the object 20 are coupled to one another. Thus, the first and second attachment means 16 and 18 may include any compatible design, system or method for successfully coupling the base component 12 and the object 20. For example, in some embodiments the first and second attachment means 16 and 18 comprise a system of interlocking disks. In other embodiments, the first and second attachment means 16 and 18 comprise a pin and dovetail coupling interaction. In other embodiments, the first and second attachment means 16 and 18 comprise a hook and loop system, such as Velcro®. Further, in some embodiment the first and second attachment means 16 and 18 comprise a magnetic coupling system.

The attachment means 14 further includes locking means for selectively coupling and separating the first and second means 16 and 18. As such, the base component 12 and the object 20 may be selectively coupled and separated as desired by a user. In some embodiments, the first and second attachment means 16 and 18 include interlocking mating surfaces that may be either engaged or separated by applying shearing force to the base component 12 and the object 20. In other embodiments, the first attachment means 16 comprises a gate whereby the second attachments means 16 is locked within the first attachment means 16 by engaging the gate. Further, in other embodiments an interfacing surface of the first attachment means 16 comprises a spring biased ball bearing that interacts with a divot located on an interfacing surface of the second attachment means 18. Thus, the interaction between the bearing and the divot temporarily interlocks the first and second attachment means 16 and 18. The first and second attachment means 16 and 18 are thereby separated by applying a shear force to the base component 12 and the object 20 that is greater than the spring force between the ball bearing and the divot.

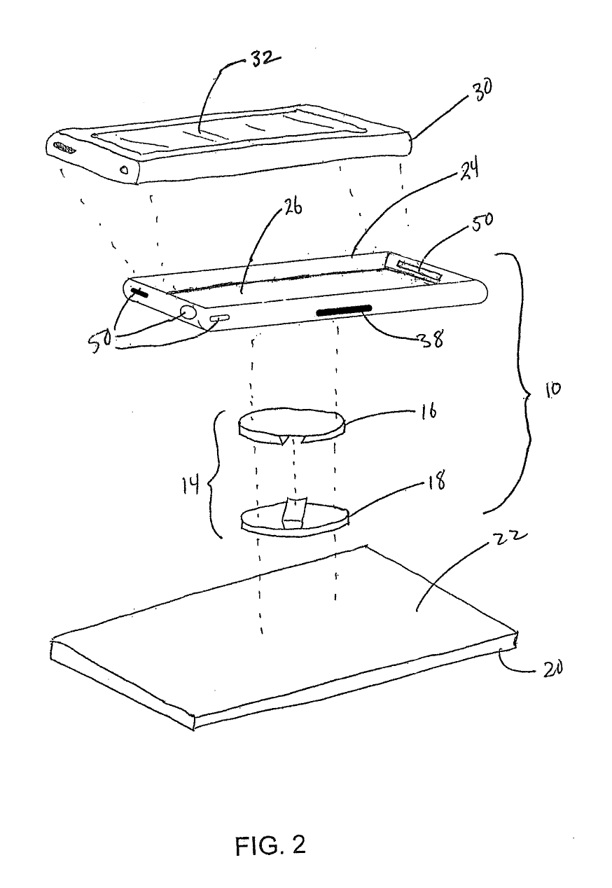

Referring now to FIG. 2, an exploded view of the hands-free system 10 is shown. In some embodiments, the base component 12 comprises a half-case having an inner compartment 26 for receiving the personal electronic device 30. In some embodiments, the base component 12 comprises a flexible, elastic polymer material that stretches to permit insertion of the personal electronic device 30 within the inner compartment 26. In other embodiments, friction between the personal electronic device 30 and the inner compartment 26 retains the device 30 within the inner compartment 26. Further, in some embodiments a permanent or temporary adhesive is interposed between the inner compartment 26 and the personal electronic device 30 to retain the device 30 within the inner compartment 26.

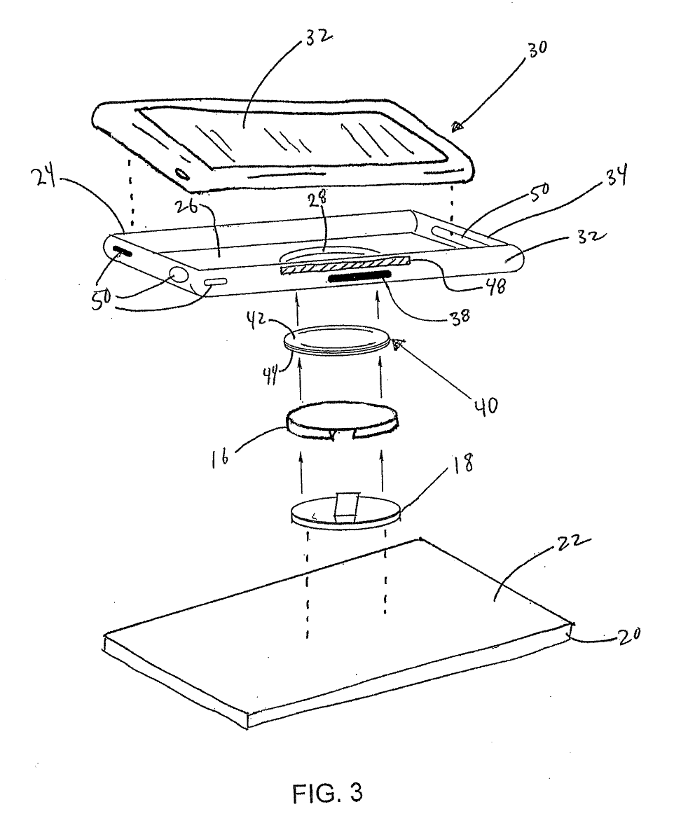

Referring now to FIG. 3, an exploded view of the hands-free system 10 is shown. In some embodiments, the hands-free system 10 further includes a swivel component 40. A swivel component 40 is provided to permit rotation of the personal electronic device 30 relative to the object 20. The swivel component 40 generally comprises a first disk 42 having a first bearing surface, and a second disk 44 having a second bearing surface forming an interface with the first bearing surface. In some embodiments, a set of bearings is further interposed between the first and second disks 42 and 44.

In some embodiments, the swivel component 40 is interposedly positioned between the base component 12 and the first attachment means 16. As such, the personal electronic device 30 is permitted to rotate relative to the first attachments 16. Therefore, when attached to a second attachment means 18, the personal electronic device 30 is permitted to rotate relative to the fixed position of the second attachment means 18. An outer surface of the first disk 42 and an outer surface of the second disk 44 are generally configured to couple to the base component 12 and the first attachment means 16, respectively. In some embodiments, the base component 12 further includes a recessed surface 28 for partially housing the swivel component 40. The recessed surface 28 is centrally located on the base component 12 and does not interfere with the seating of the electronic device 30. When the swivel component 40 is set within the recessed surface 28, the profile height of the hands-free system 10 is minimized.

In some embodiments, the swivel component is interposedly positioned between the second attachment means 18 and the object 20. Thus, the second attachment means 18 is permitted to rotate relative to the fixed position of the object. Therefore, when the first attachment means 16 is coupled to the second attachment means 18, the personal electronic device 30 is permitted to rotate relative to the fixed position of the object 20. Further, in some embodiments a first swivel means 40 is interposedly positioned between the first attachment means 16 and the base component 12, and a second swivel means (not shown) is interposedly positioned between the second attachment means 18 and an object 20.

In some embodiments, the bearing surfaces of the first and second disks 42 and 44 further include a plurality of interlocked positions, such that a user may selectively rotate the personal electronic device 30 to a desired position relative to the object 20. The plurality of interlocked positions enables a user to adjust and maintain the orientation of the electronic device 30 as desired. For example, in some embodiments a user may desire to position and maintain a personal electronic device 30 in a landscape orientation. In other embodiments, a user may desire to position and maintain a personal electronic device 30 in a portrait orientation. Thus, the plurality of interlocked positions enables a user to rotate and set a desired orientation of the personal electronic device 30 relative to a set orientation of an attached object 20. Conversely, the plurality of interlocked positions enables a user to rotate and maintain a desired, set orientation of a personal electronic device 30 relative to a moving orientation of an attached object 20.

In some embodiments, the first and second disks 42 and 44 freely rotated relative to one another. As such, the position of the personal electronic device 30 is not restrained to a specific position relative to the object 20. Rather, the position of the personal electronic device 30 may voluntarily or involuntarily be rotated relative to the object 20. In some embodiments, the base component 12 further comprises a ballast weight 48. The ballast weight 48 is generally provided to increase the weight of one edge of the base component 12 relative to remaining, unweighted edges. The edge containing the ballast weight 48 naturally assumes a position lower than the unweighted edges. Thus, as the object 20 is rotated, the edge of the base component 20 containing the ballast weight 48 remains in a low, fixed position. Therefore, if the ballast weight 48 is positioned on a first edge 32 of the base component 12, the electronic device 30 will maintain a landscape orientation regardless of the changing orientation of the object 20. Similarly, if the ballast weight is positioned on a second edge 34 of the base component 12, the electronic device 30 will maintain a portrait orientation regardless of the changing orientation of the object 20. Thus, in some aspects of the present invention a ballast weight 48 is used in combination with a freely rotating swivel component 40 permit rotation of an object 20 while maintaining a desired orientation of the electronic device 30.

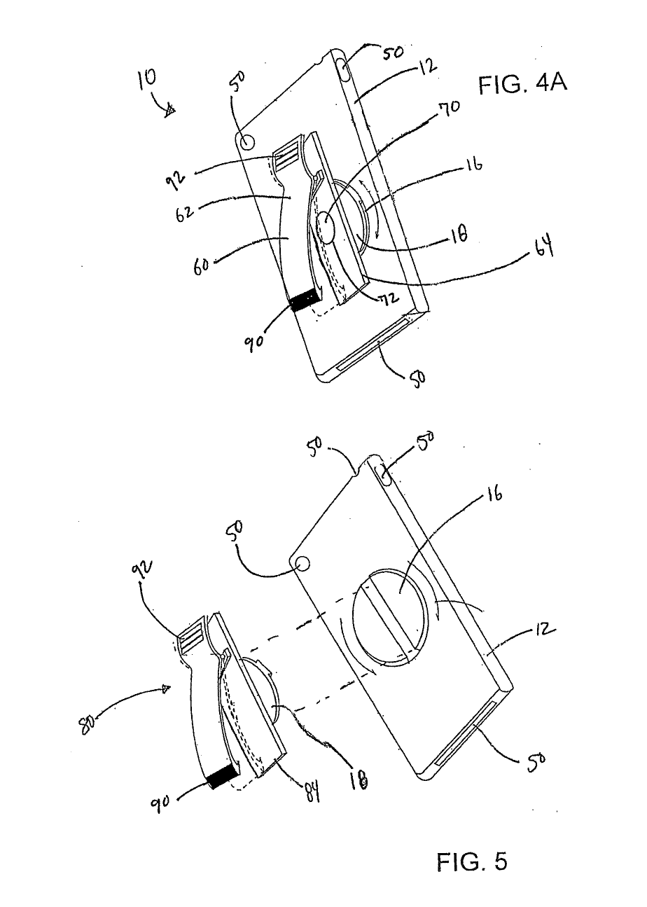

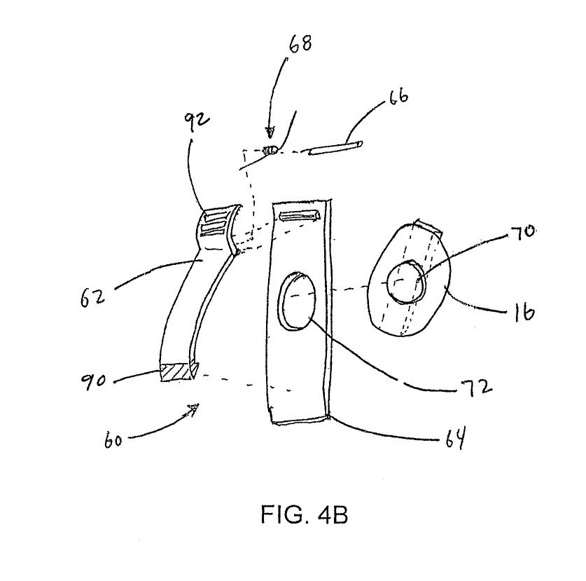

Referring now to FIG. 4A, a hands-free system is shown in combination a swivel clip 60. In some embodiments, a swivel clip 60 is coupled to the base component 12 via a first and second attachment means 16 and 18. The swivel clip 60 generally comprises a spring clip 62 hingedly coupled to a clip base 64 via a pin 66 and spring 68, as shown in FIG. 4B. Unlike the previous embodiments, the embodiment of FIG. 4A does not include a swivel component. Rather, the second attachment means 18 is modified to include a post 70 configured to compatibly and rotatably couple an aperture 72 of the clip base 64. As such, the post 70 and aperture 72 rotate relative to one another, but are prevented from being separated. Thus, in some embodiments the swivel clip 60 is coupled to an object 20 in a fixed position, and the base component 12 is permitted to rotate relative to a fixed position of the swivel clip 60.

Referring now to FIG. 5, in some embodiments of the present invention a second attachment means 18 is fixedly coupled to a clip 80. The clip 80 is similarly configured to the swivel clip 60 of FIGS. 4A and 4B, but does not include means to enable the clip 80 to rotate relative to the second attachment means 168. Rather, the clip base 84 is directly and fixedly coupled to the second attachment means 18. However, a first attachment means 16 is rotatably coupled to the base component 12, as previously discussed in connection with FIGS. 1-3. Thus, in some embodiments the second attachment means 18 and the first attachment means 16 are coupled to one another, permitting the base component 12 to rotate relative to the clip via a swivel component 40 interposedly coupled between the first attachment means 16 and the base component 12. As such, in some aspects of the present invention the clip 80 is coupled to an object 20 in a fixed position, and the base component 12 is permitted to rotate relative to the fixed positions of the clip 80 and the second attachment means 18.

The swivel clip 60 and the clip 80 may further include features configured to assist a user in using the clip. For example, in some embodiments the clip 80 and the swivel clip 60 further comprise a rubber coated tip 90. The rubber coated tip 90 provides an increased coefficient of friction for the tip portion of the clips 60 and 80 which helps to prevent slippage between the clips 60 and 80 and the attached object 20. In other embodiments, the clips 60 and 80 further include a non-slip contact pad 92. The contact pad 92 increases the coefficient of friction between the clips 60 and 80 and the user's finger, to help prevent slippage when activating the clips 60 and 80.

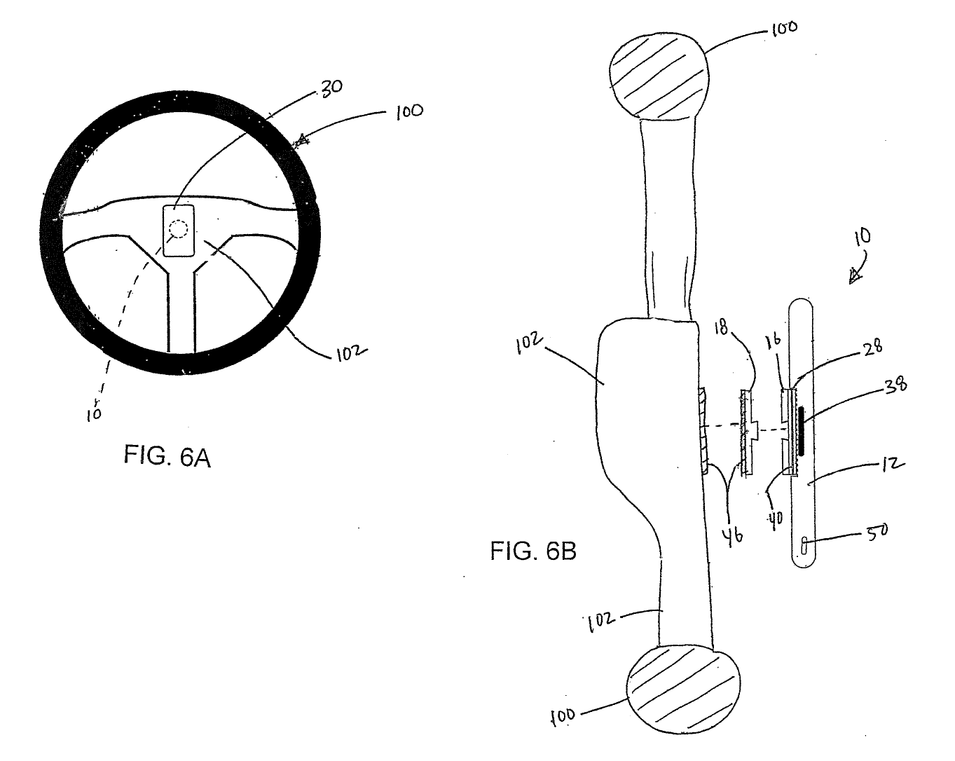

One of skill in the art will appreciate that the hands-free system 10 of the present invention may be used in combination with a variety of compatible user applications. For example, referring now to FIG. 6A a representative embodiments in accordance with the present invention is shown. The hands-free system of the present invention may be utilized to attach a personal electronic device 30 to a steering wheel 100 of a vehicle. In some embodiments, a personal electronic device 30 (such as a personal navigation device) is mounted to a cross-member portion 102 of a steering wheel 100 so that a user may view a map or driving direction while operating a vehicle. In other embodiments, a personal electronic device 30 (such as an iPhone®) is mounted to a cross-member portion 102 of a steering wheel 100 so that a user may carry on a conversation while keeping both hands on the steering wheel 100.

Referring now to FIG. 6B, an exploded view of a cross-sectional steering wheel and hands-free system 10 is shown. In some embodiments, the second attachment means 18 is coupled to a cross-member portion 102 of a steering wheel via a hook and loop fastener 46, such as Velcro®. The hook and loop fastener 46 is generally centrally positioned on the cross-member portion 102 of the steering wheel 100. In some embodiments the hook or loop portion of the fastener 46 is installed on the cross-member portion 102 during manufacturing of the vehicle. In other embodiments, the hook or loop portion of the fastener 46 is retro fit on the cross-member portion 102 of the steering wheel 100. Further, in some embodiments the portion of the fastener 46 coupled to the cross-member portion 102 of the steering wheel 100 is configured to include a symbol, logo or trademark of the respective vehicle manufacturer to minimize or mask the presence of the fastener.

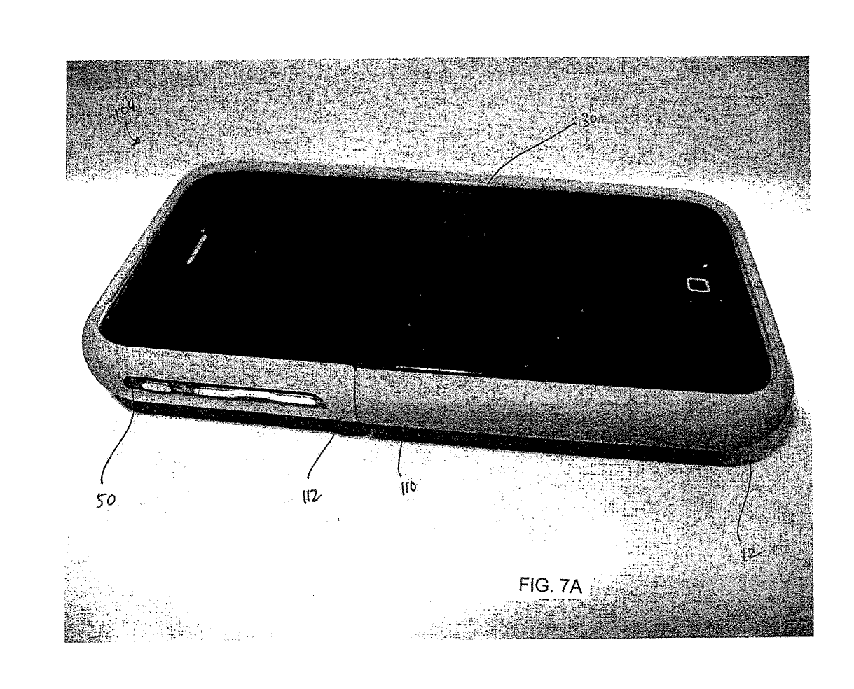

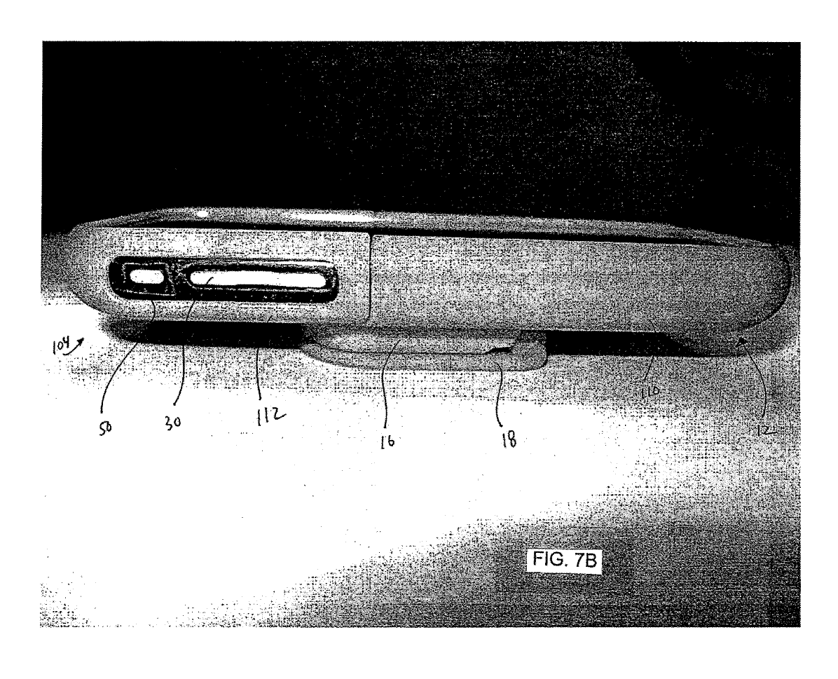

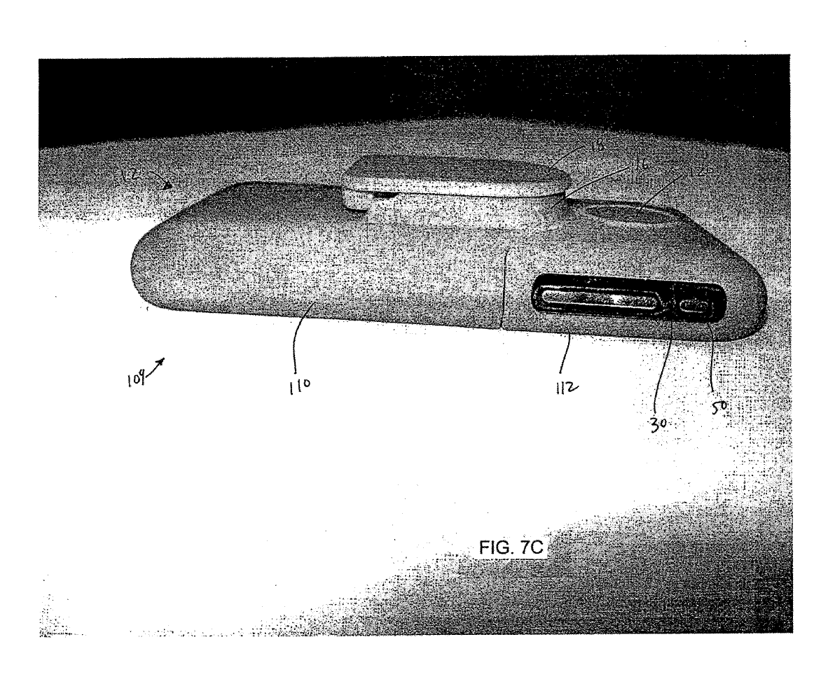

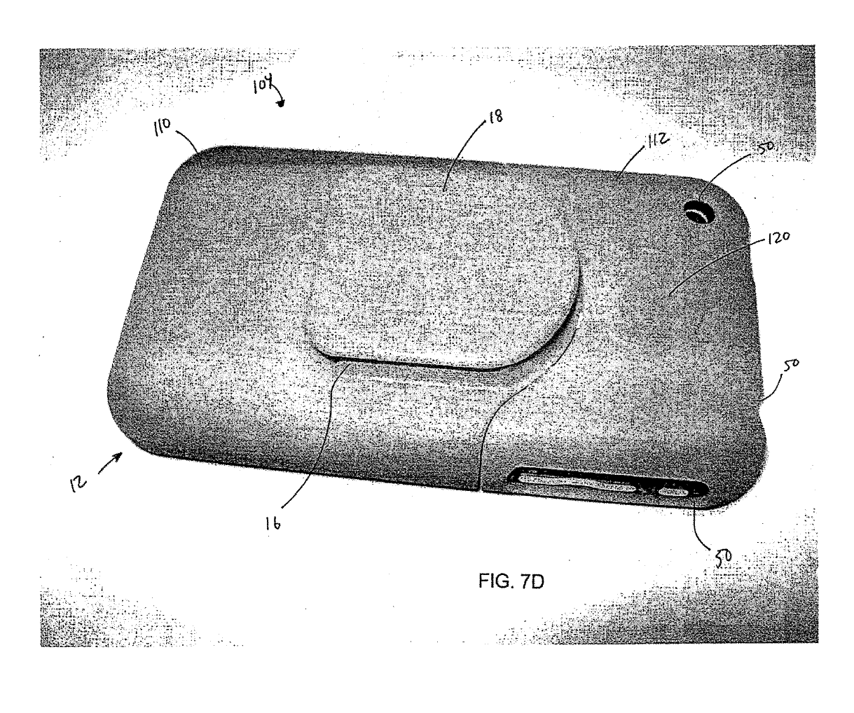

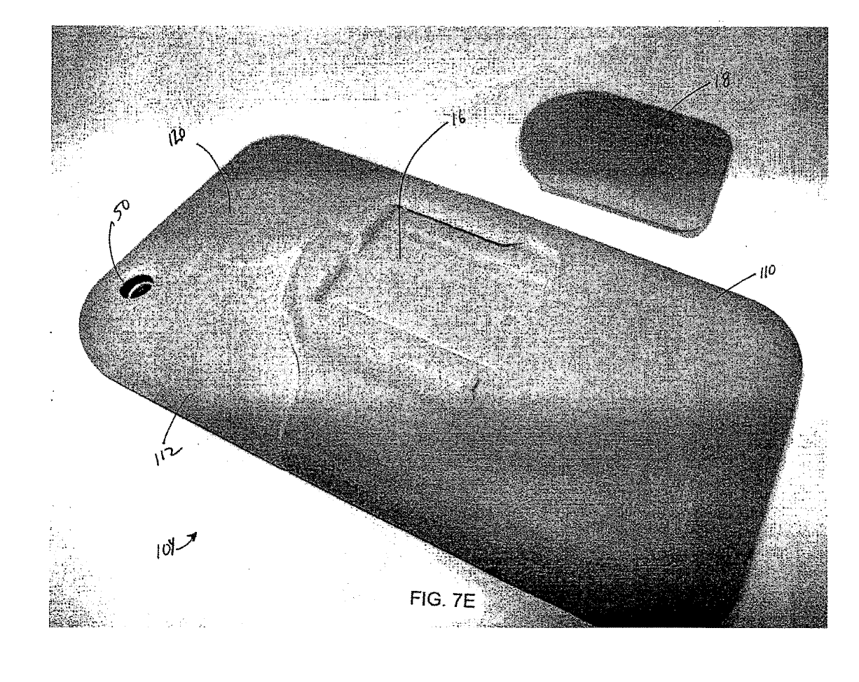

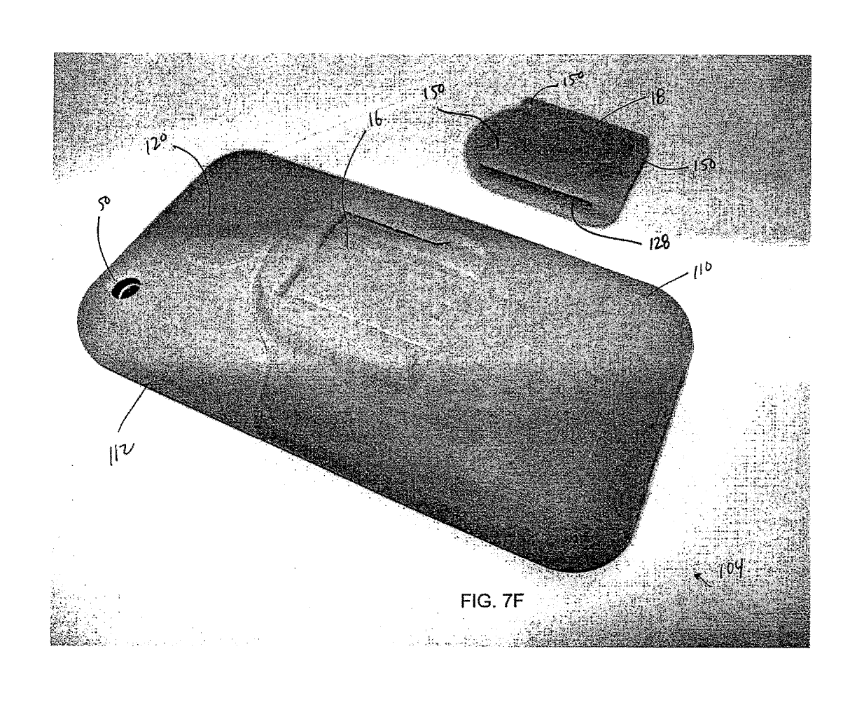

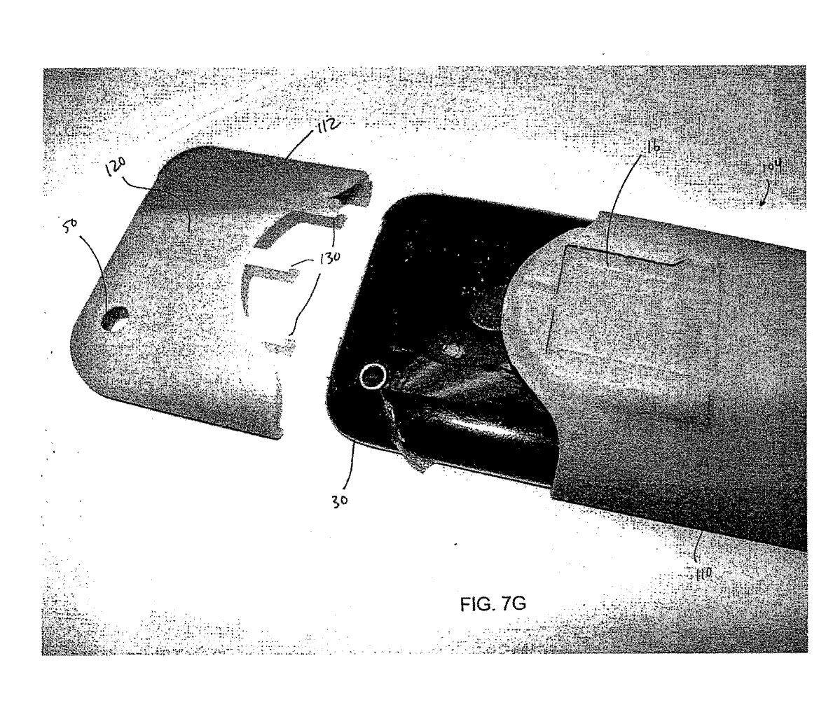

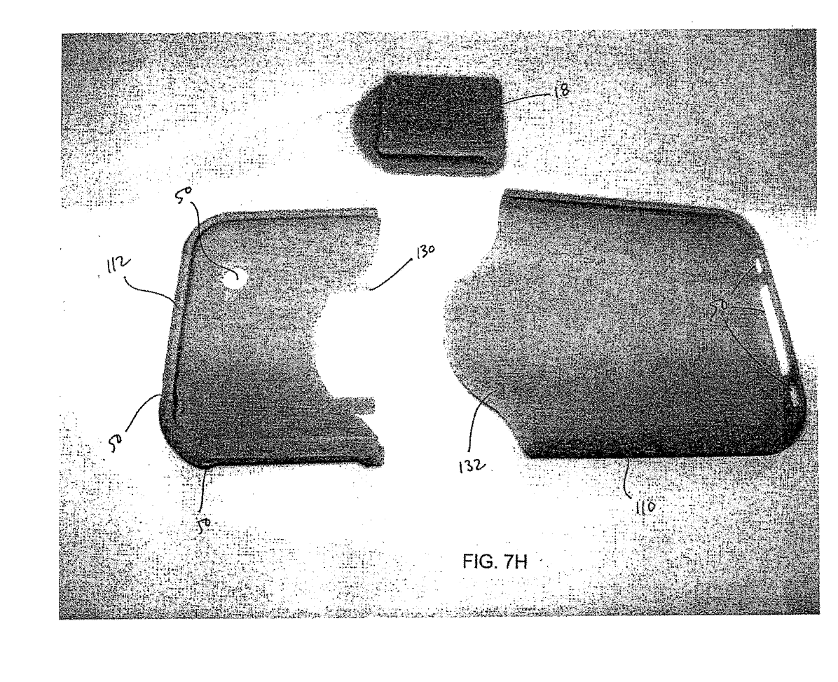

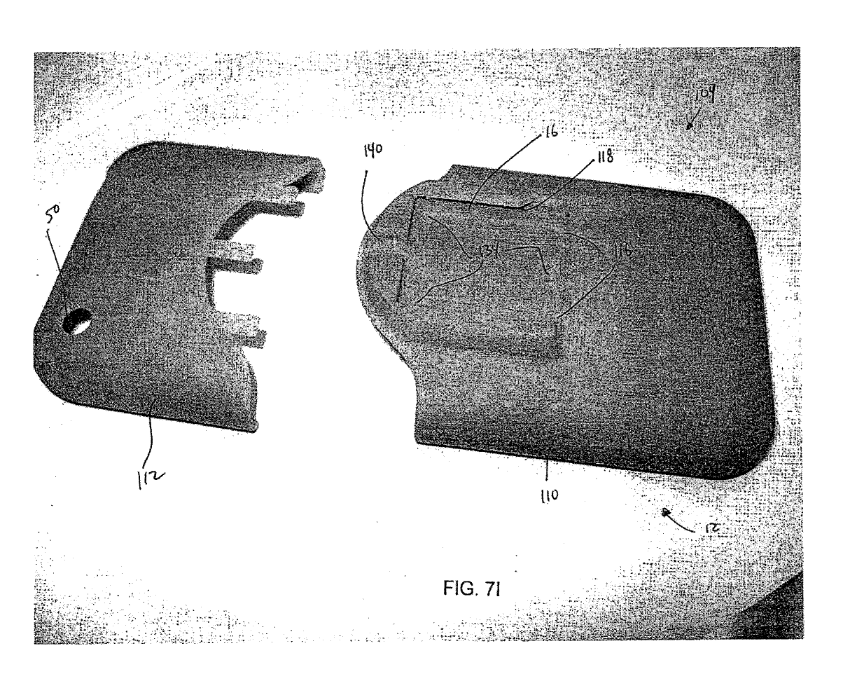

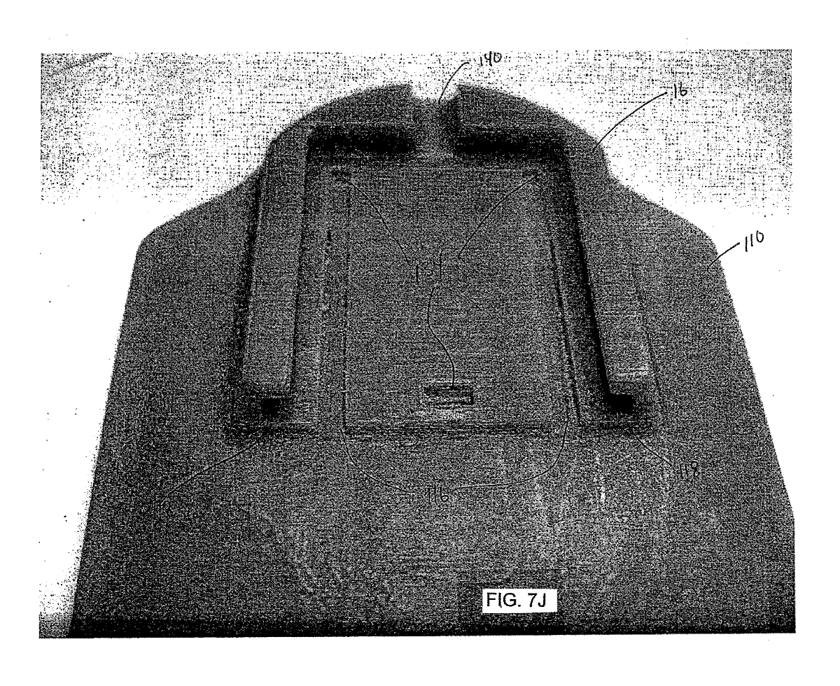

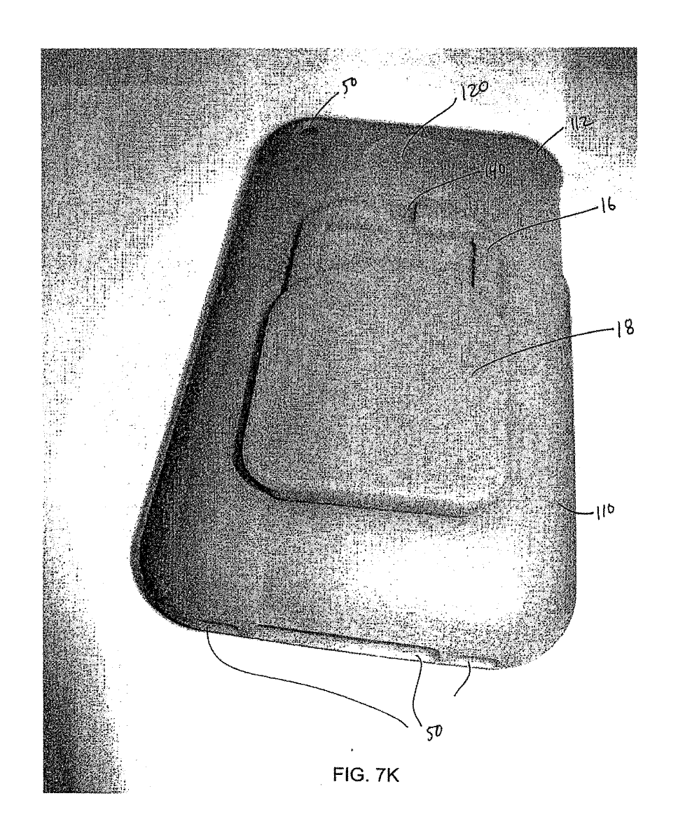

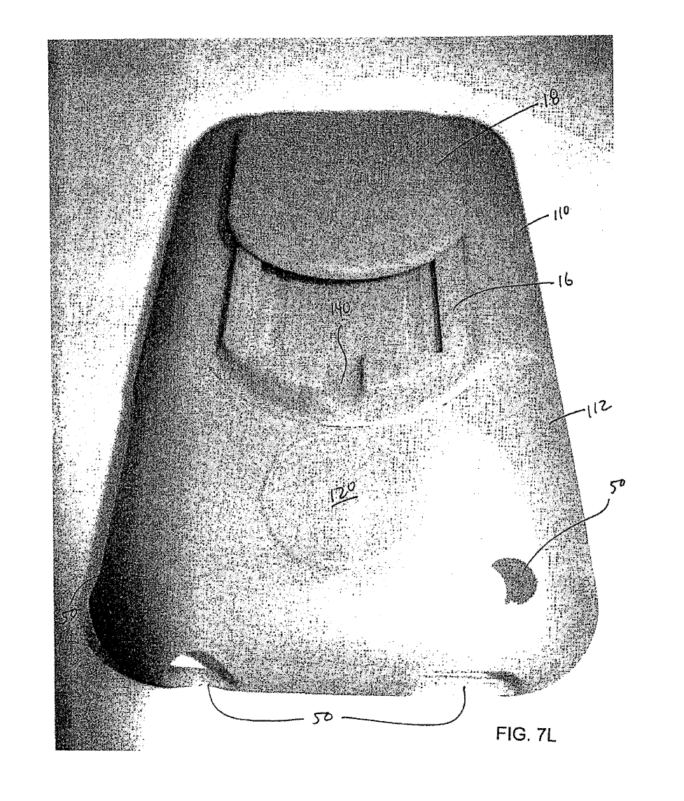

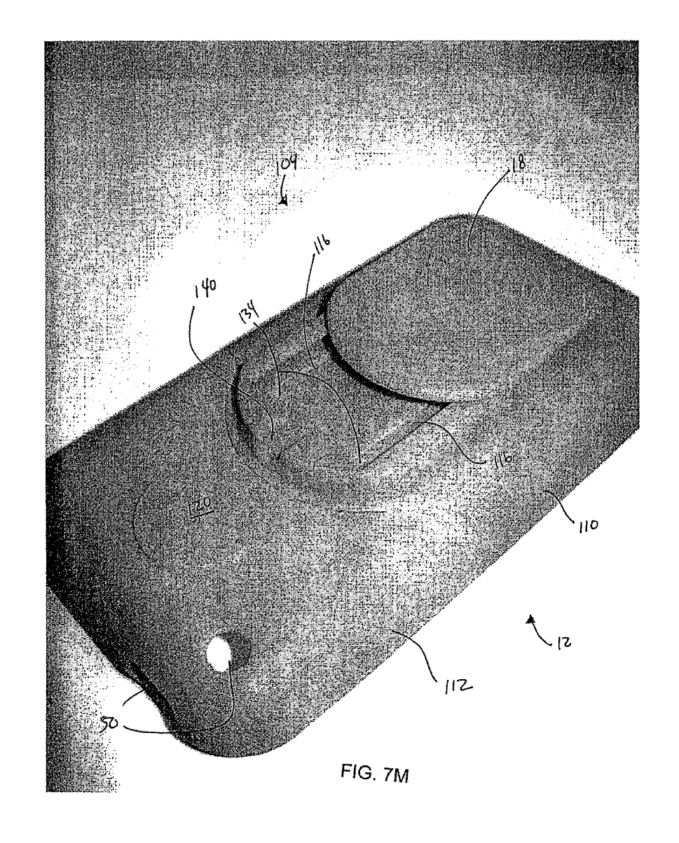

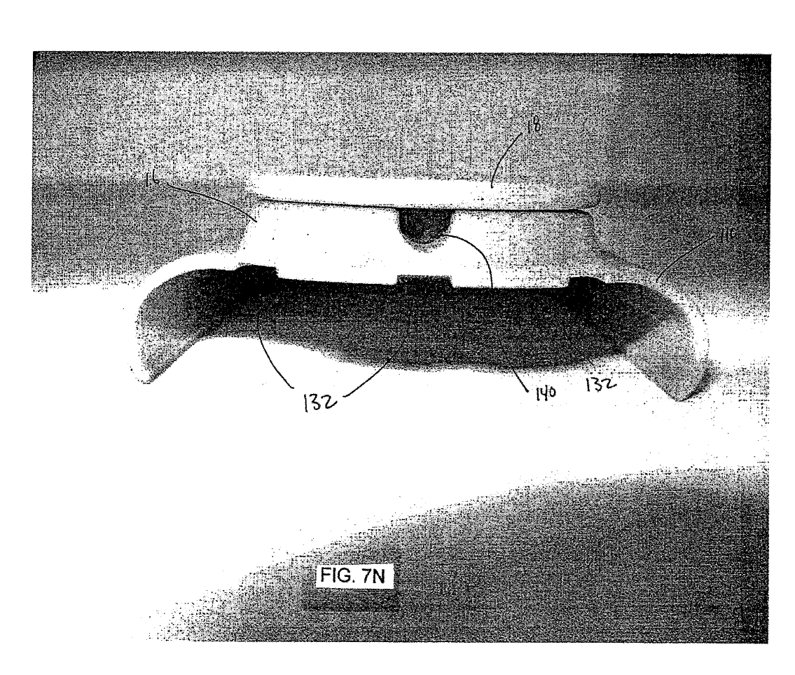

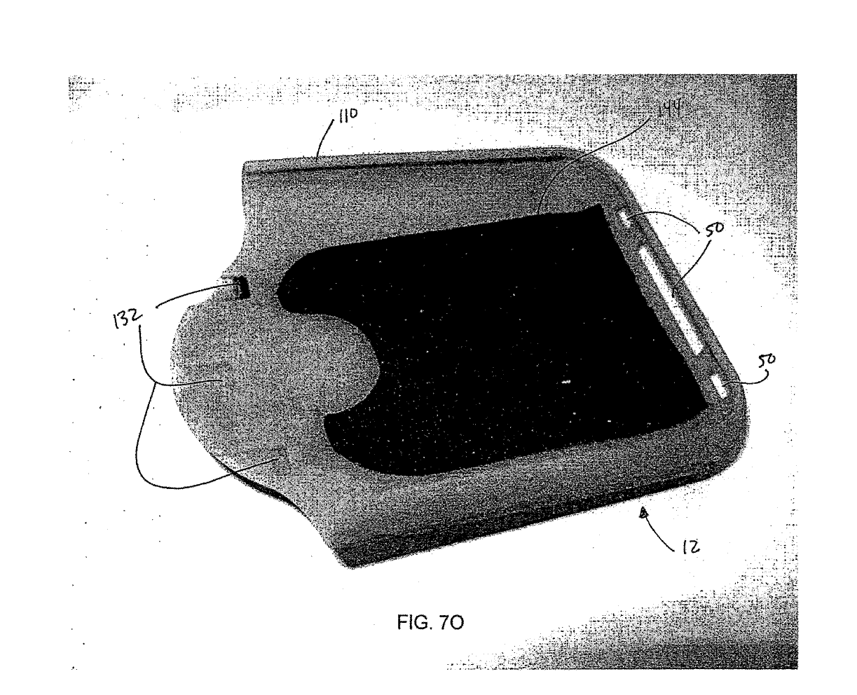

Referring now to FIGS. 7A-7N, a two-piece, hands-free system 104 is shown. In some embodiments, the hands-free system comprises a shell having a first half 110 and a second half 112. The first and second halves 110 and 112 are coupled together to provide an outer casing, as shown. In some embodiments, first half 110 further comprises a first attachment means 16. First attachment means 16 may comprises a molded portion of first half 110, as shown in FIGS. 7B-7G and 7I-7N.

In some embodiments, attachment means 16 is configured to compatibly receive and selectively retain second attachment means 18, as shown in FIGS. 7B-7D, 7K-7N. Second attachment means 18 generally comprises compatible features to enable selective coupling to attachment means 16. For example, in some embodiments attachment means 16 comprises receiving channels 118, alignment tracks 116, and detents 134 to guide and assist reception of second attachment means 18. Second attachment means 18 further comprises corresponding alignment channels 128 and pegs 150 to assist in coupling.

In some embodiments, hands-free system 104 further comprises a surface 120 for accommodating a label, such as a school insignia. In other embodiments, surface 120 comprises opening for interchangeably receiving an insignia button or plaque, as desired by a user.

In some embodiments, first half 110 is used independently of second half 112, as shown in FIG. 7G. In other embodiments, first half 110 and second half 112 are coupled together via a plurality of clips 130 and detents 132. In other embodiments, first half 110 and second half 112 are coupled together via a friction interface between the halves and the personal electronic device 30.

In some embodiments, first or second halves 110 and 112 may further include an insert 140 to fill a gap between the shell and the personal electronic device 30. For example, in some embodiments insert 140 comprises a felt spacer. In other embodiments, first attachment means 16 further comprises a channel 140 thereby providing a forward pathway between the second attachment means 18 and the first attachment means 16.

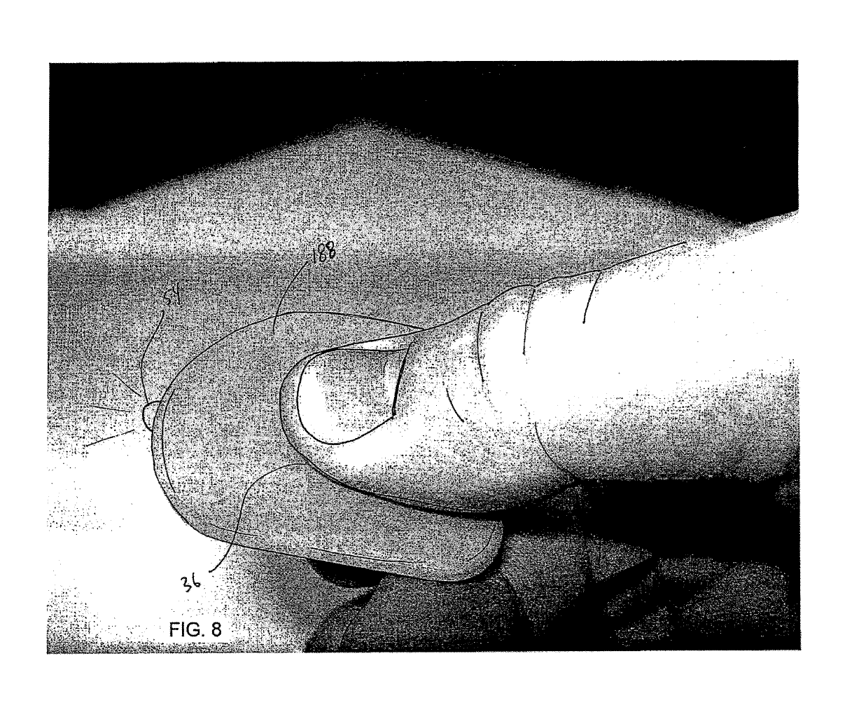

In some embodiments, channel 140 provides a pathway for a flashlight adaptation of second attachment mean 188, as shown in FIG. 8. Second attachment means 188 comprises an LED light 54 that is activated by depressing button 36. Thus, second attachment means 188 provides a dual function of both coupling to first attachment means 16 and serving as a flashlight.

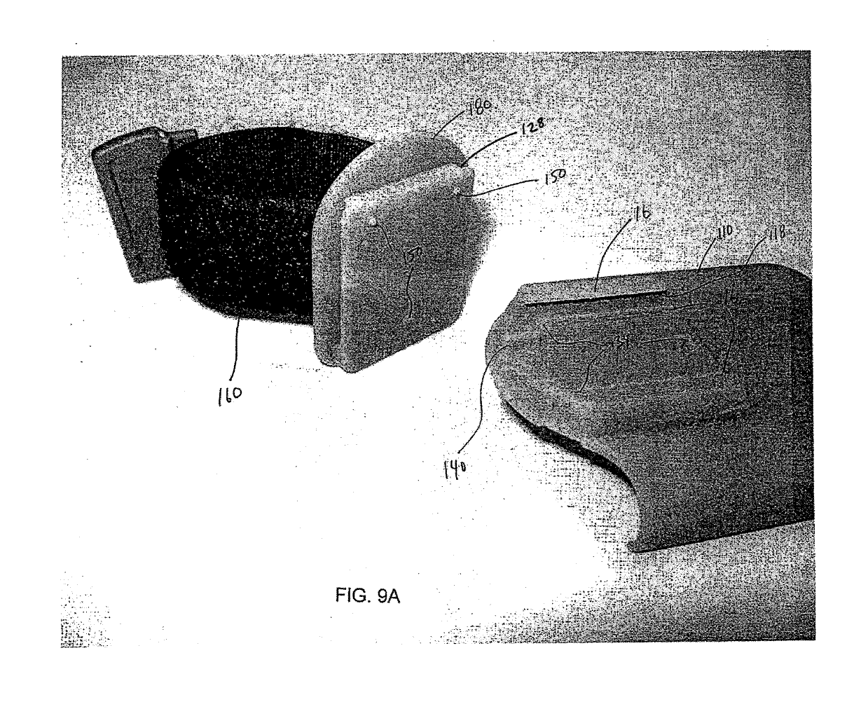

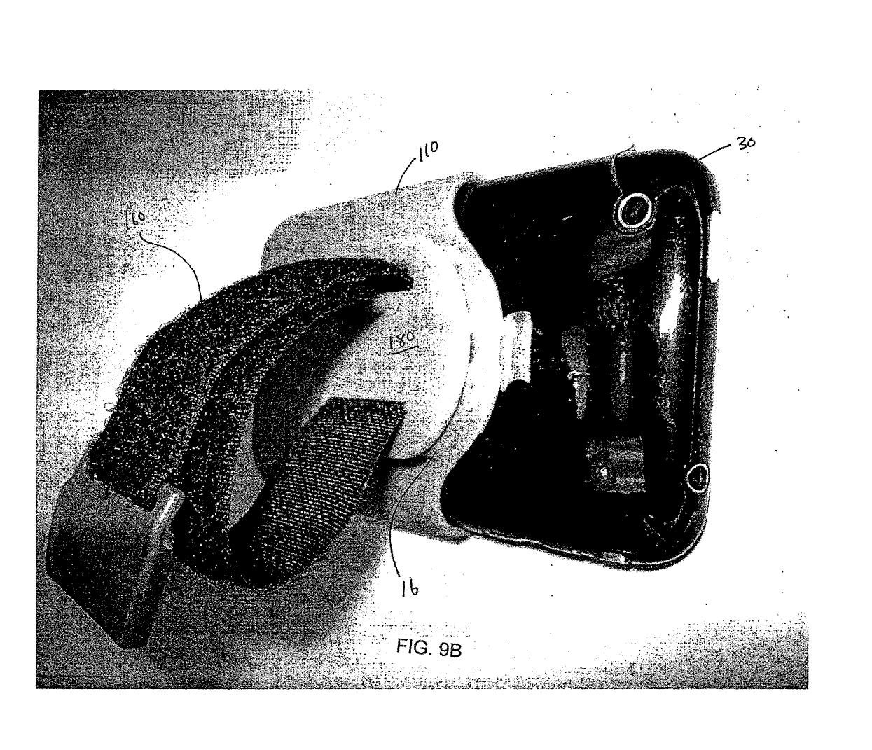

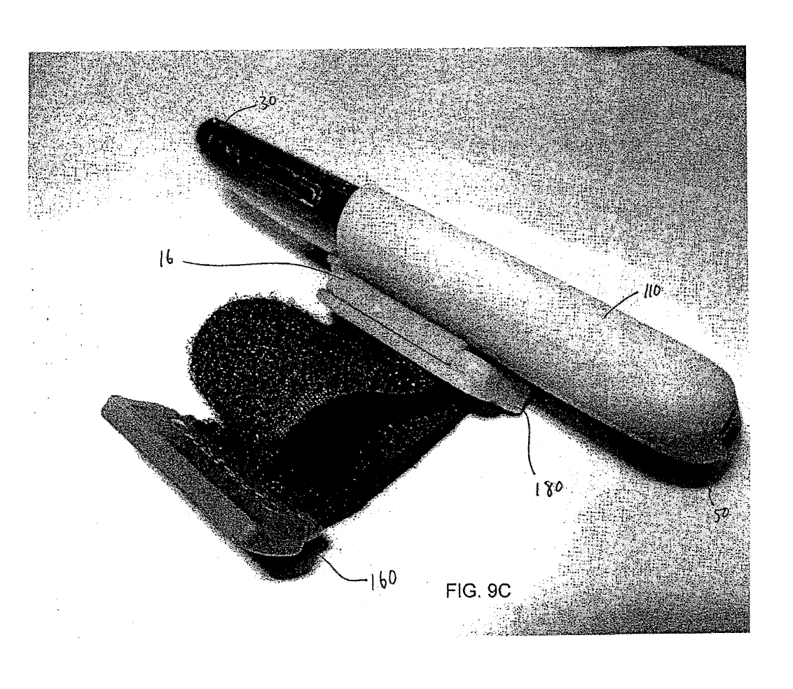

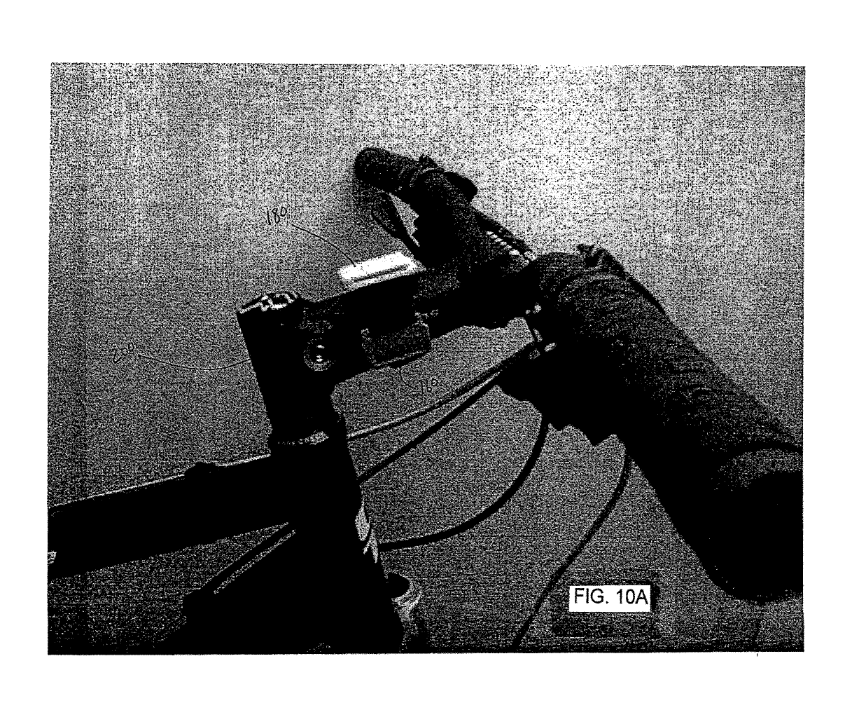

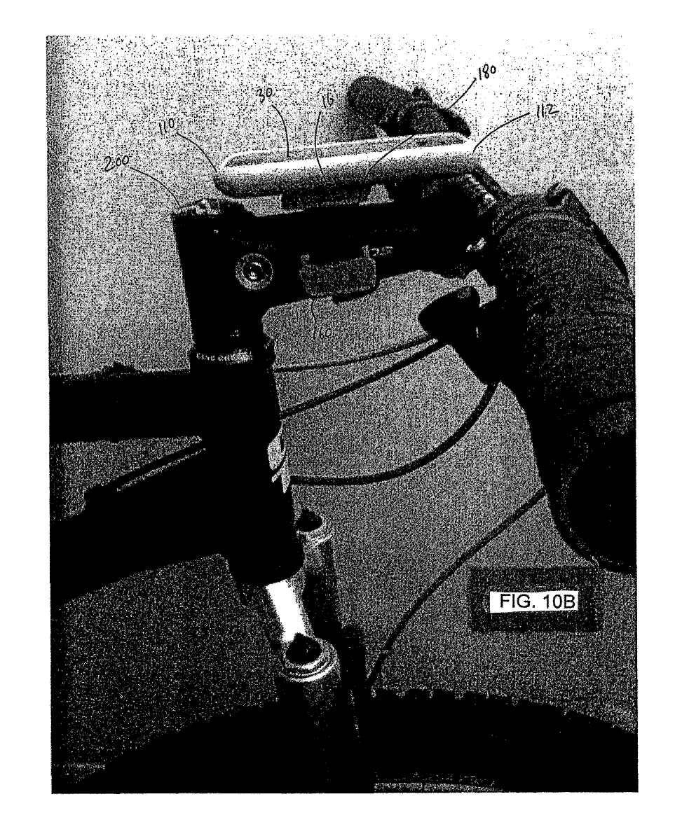

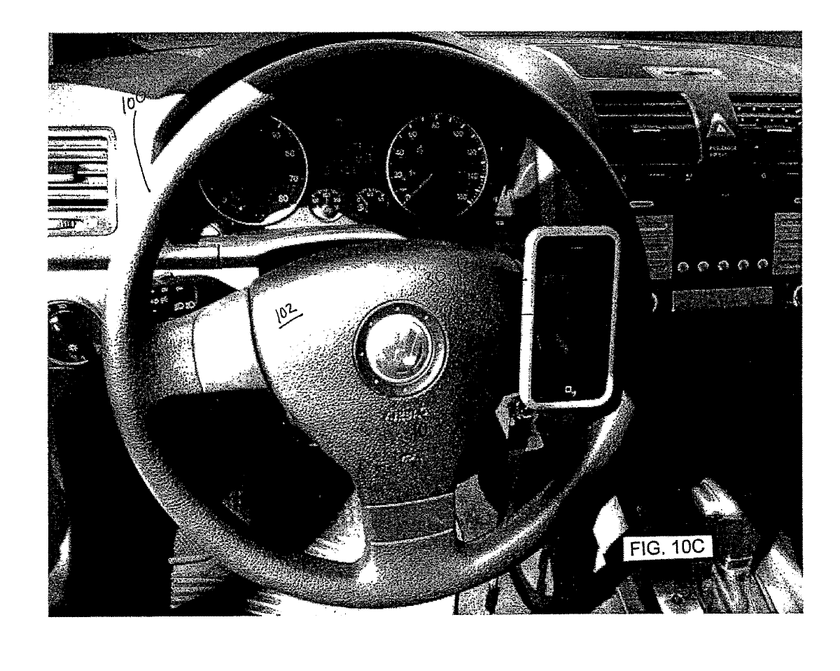

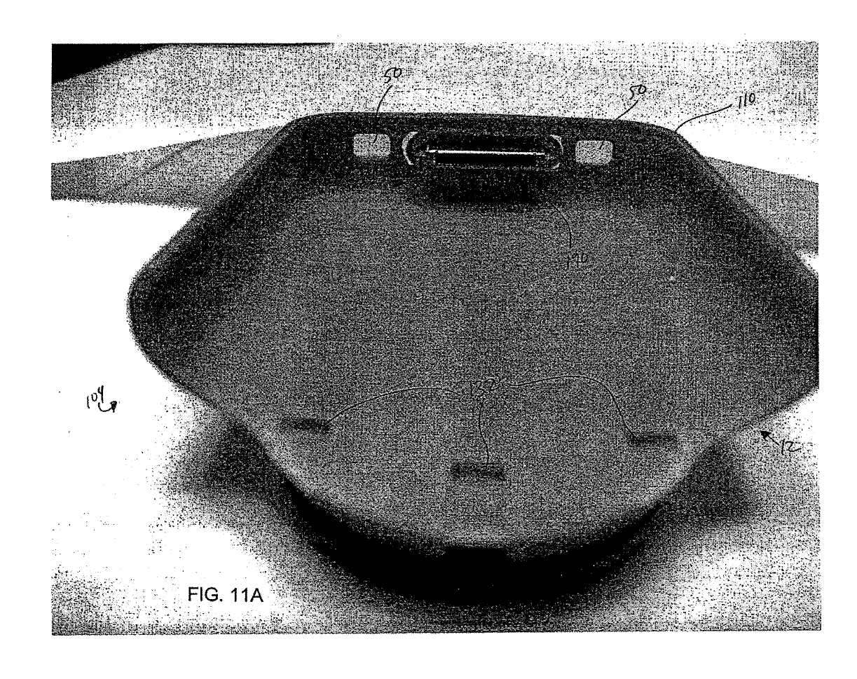

Referring now to FIGS. 9A-9C, retention strap 160 is shown as coupled to second attachment means 180. In some embodiments, second attachment means 180 is coupled to a desired device via retention strap 160. For example, in some embodiments attachment means 180 is attached to a bicycle 200 via retention strap 160, as shown in FIGS. 10A and 10B. In other embodiments, second attachment means 180 alternatively comprises a rigid ring mount (not shown) whereby the second attachment means 180 is securely and rigidly fastened to a desired portion of bicycle 200. Retention strap 160 may further be used to couple second attachment means 180 to a steering wheel 102, as shown in FIG. 10C.

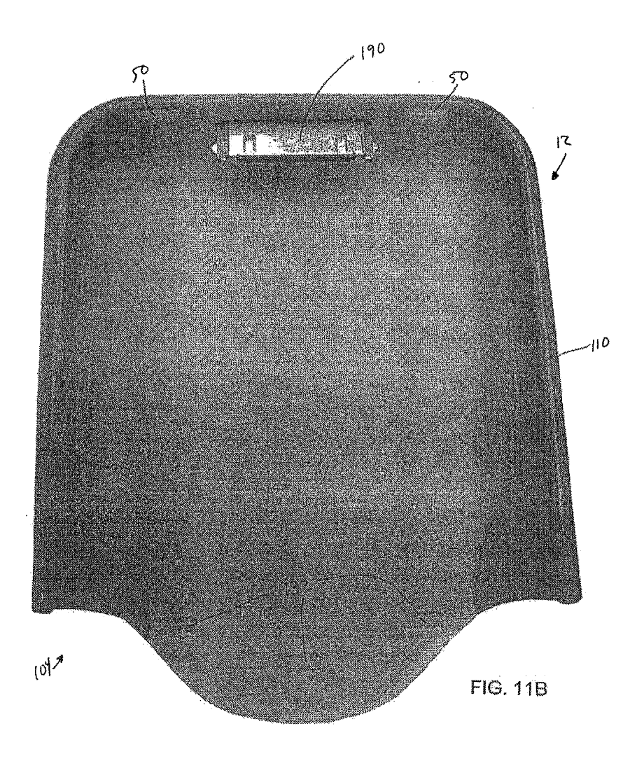

Referring now to FIGS. 11A and 11B, hand-free system 104 may further include an electrical connector 190. In some embodiments, electrical connector 190 is positioned within first half 110 such that electrical connector 190 couples electronic device 30 upon insertion of electrical device 30 into first half 110. In some embodiments, electrical connector 190 is electrically coupled to electrical contacts disposed in first attachment means 16. Thus, an electrical connection is provided between personal electronic device 30 and attachment means 16 via electrical connector 190 and a circuitry of electrical contacts (not shown).

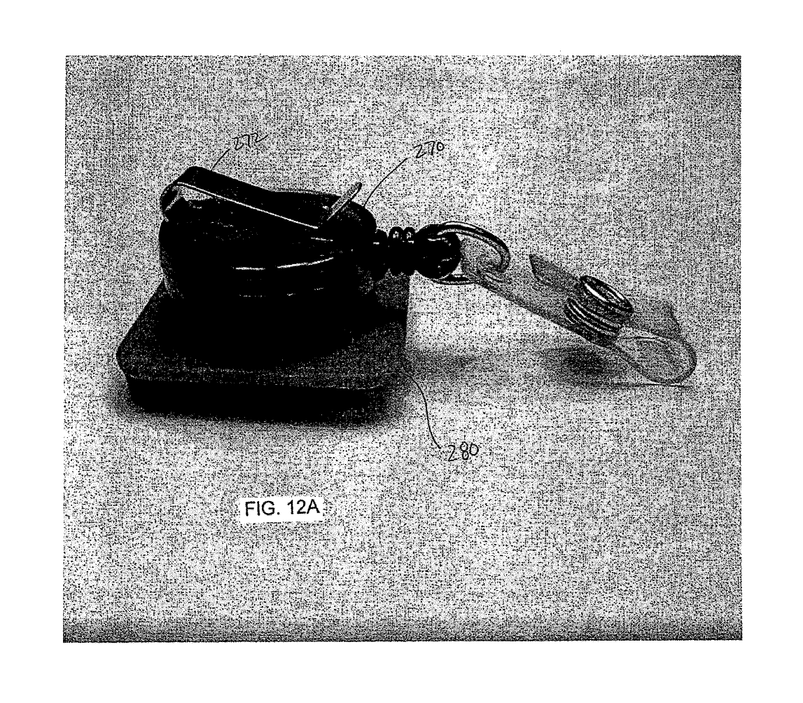

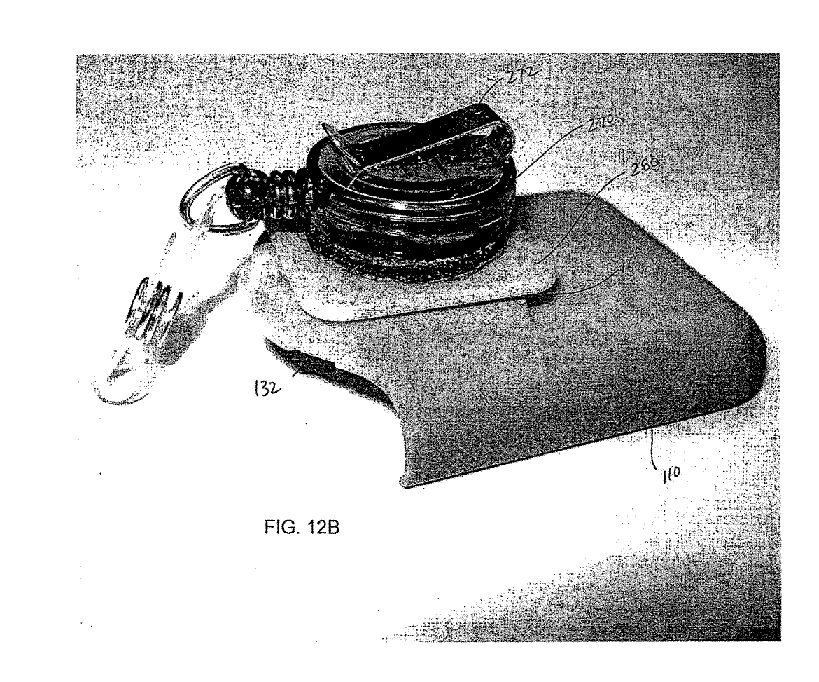

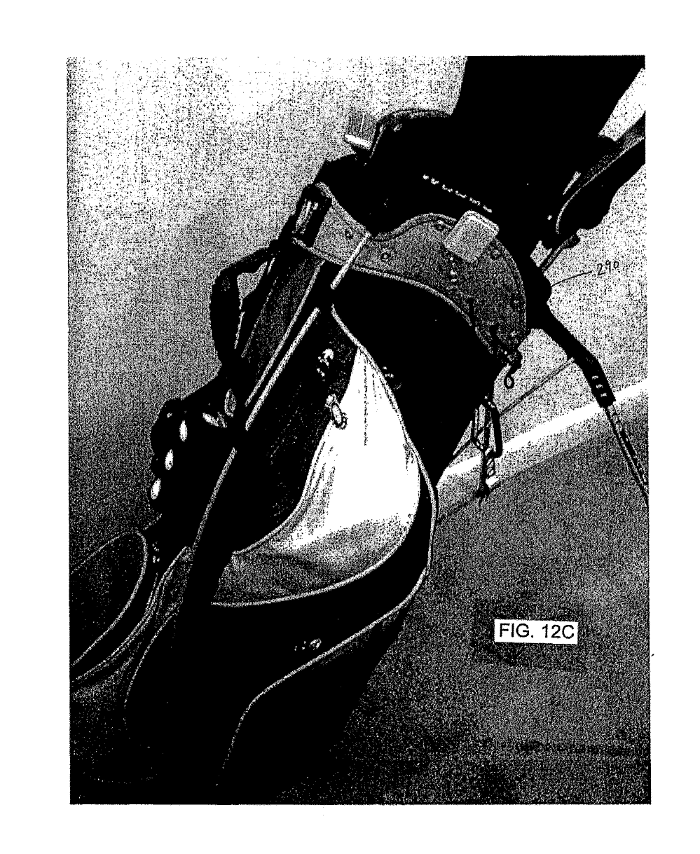

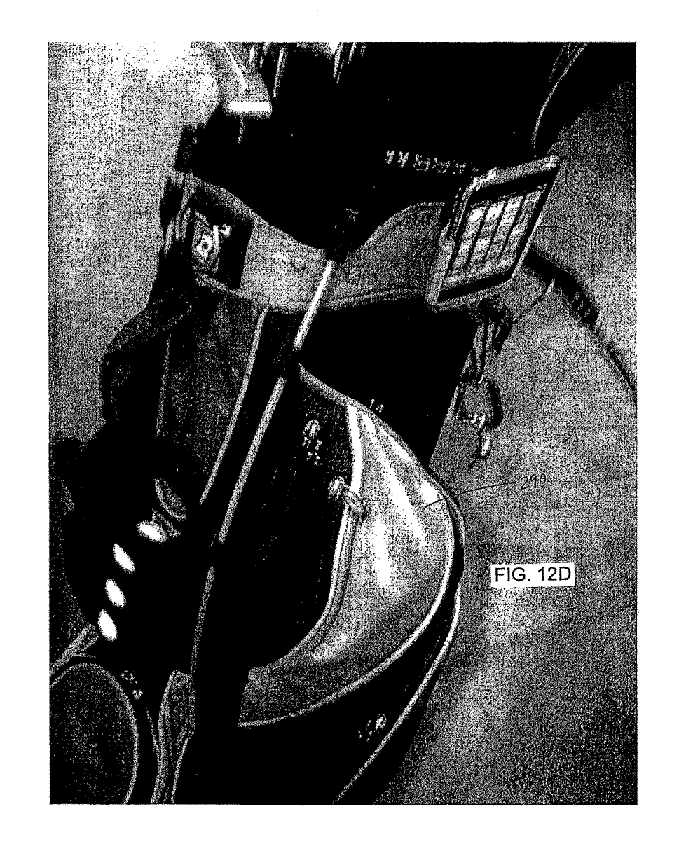

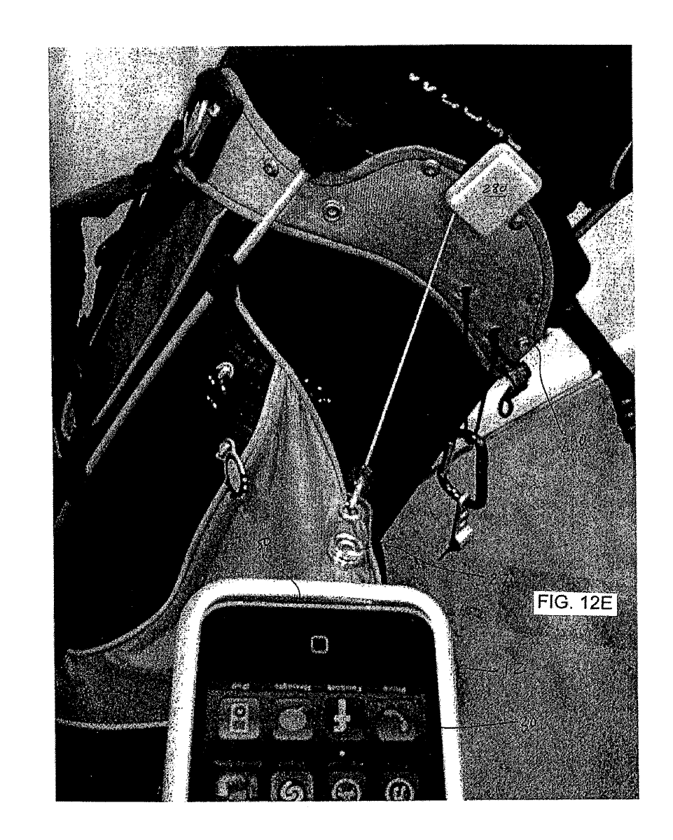

Referring now to FIGS. 12A-12E, hands-free system 104 may further include a lanyard attachment means 280. In some embodiments, attachment means 280 is modified to include a retractable lanyard 270. In some embodiments, lanyard 270 comprises a belt clip 272 whereby attachment means 280 is secured to a desired surface, such as a golf bag 290. Electronic device 30 may then be removed from the golf bag 290 by removing first half 110 from attachment means 280, as shown in FIG. 12C. Alternatively, lanyard 270 may be attached to a hole 50 of hands-free system 104 whereby the retractable nature of lanyard 270 permits temporary removal of the device 30 from the golf bag 290.

A method in accordance with the present invention, for attaching a personal electronic device to an object includes the steps of providing a base component, coupling the base component to a personal electronic device, coupling the base component to a first attachment means, coupling a second attachment means to an object, and coupling the first attachment means to the second attachment means. Additional methods in accordance with the present invention further include the steps of interposedly coupling a swivel component between the first attachment means and the base component. Alternatively, the step of interposedly coupling a swivel component between the first attachment means and the base component may be replaced by the step of interposedly coupling a swivel component between the second attachment means and an object. Further, some methods in accordance with the present invention interposedly position a first coupling means between the first attachment means and the base component, and interposedly position a second coupling means between the second attachment means and the object.

Thus, as discussed herein, the embodiments of the present invention generally relate to a hands-free system for attaching a personal electronic device to an object. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A system for attaching a personal electronic device to a surface, the system comprising:
a base component directly coupled to an outer surface of the personal electronic device, the base component having a first attachment means; and
a second attachment means coupled to the surface; wherein the first attachment means and the second attachment means compatibly attach to one another, thereby attaching the personal electronic device to the surface.

2. The system of claim 1, further comprising a swivel component interposedly coupled between the base component and the first attachment means.

3. The system of claim 1, further comprising a swivel component interposedly coupled between the second attachment means and the surface.
